(19) United States
(12) Patent Application Publication
(10) Pub. No.: US 2008/0211385 A1
(43) Pub. Date: Sep. 4, 2008

(54) ORGANIC ELECTRO-LUMINESCENT DISPLAY

(75) Inventors: Sang-yeol KIM, Yongin-si (KR); Mu-gyeom KIM, Yongin-si (KR); Sung-hun LEE, Yongin-si (KR); Jung-bae SONG, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/017,444

(22) Filed: Jan. 22, 2008

(30) Foreign Application Priority Data
Jan. 22, 2007 (KR) 10-2007-0006706

(51) Int. Cl. H01J 1/62

(52) U.S. Cl. 313/498

(57) ABSTRACT

Provided is an organic electro-luminescent display (OELD). The OELD includes: a plurality of unit pixels having an organic light emitting unit and a driving unit for driving the organic light emitting unit; and a substrate supporting the unit pixels, wherein the substrate has a non-planar portion corresponding to the light emitting unit and increasing a surface area, and the light emitting unit has a non-planar cross-sectional shape corresponding to the non-planar portion. The OELD has a concave portion or a convex portion for enlarging a surface such that the substantial area of an organic light emitting material increases. Thus, an effective light emission area increases in a pixel having a limited area and light emission of desired high brightness can be performed by a low driving voltage. A reduction in a driving voltage causes improvement in the durability of a pixel and the life span of the OELD is enlarged.

### CROSS-REFERENCE TO RELATED PATENT APPLICATIONS

This application claims the benefit of Korean Patent Application No. 10-2007-0006706, filed on Jan. 22, 2007, in the Korean Intellectual Property Office, the disclosure of which incorporated herein in its entirety by reference.

### BACKGROUND OF THE INVENTION

1. Field of the Invention

The present invention relates to an organic electro-luminescent display (OELD), and more particularly, to an OELD having an improved aspect ratio.

2. Description of the Related Art

Generally, organic electro-luminescent displays (OELDs) are display devices in which electron holes supplied from an anode electrode and electrons supplied from a cathode electrode are combined within an organic light emitting layer formed between the anode electrode and the cathode electrode, thereby emitting light and forming an image. Such OELDs are one type of flat panel displays (FPDs) and show excellent display characteristics such as excellent color reproducibility, fast response, spontaneous light emitting, a ultra-small size, a high contrast ratio, a wide view angle, and low power consumption. These OELDs have been densely researched as next-generation displays and large size and high definition of high quality are required according to market demands like in other displays.

However, as displays have been manufactured for higher definition, a driving circuit becomes more complicated so that the area of a driving circuit in a unit pixel region increases and the area of an organic light emitting unit such as a diode in which light emission is performed is reduced. That is, the high definition of displays causes a reduction in an aspect ratio and the light emission brightness of a unit pixel is lowered. Thus, in order to compensate a reduction in brightness caused by a reduction in an aspect ratio, an increase in a light emission intensity per pixel is required. Such an increase in a light emission intensity requires an increase in a driving voltage and the life span of the organic light emitting unit is reduced as a driving voltage increases.

### SUMMARY OF THE INVENTION

The present invention provides an organic electro-luminescent display (OELD) to improve an aspect ratio of a light emitting unit in a pixel having a limited size.

The present invention also provides an OELD to improve durability due to a reduction in a driving voltage according to improvement in an aspect ratio.

According to an aspect of the present invention, there is provided an organic electro-luminescent display (OLED) comprising: a plurality of unit pixels having an organic light emitting unit and a driving unit for driving the organic light emitting unit; and a substrate supporting the unit pixels, wherein the substrate has a non-planar portion corresponding to the light emitting unit and increasing a surface area, and the light emitting unit has a non-planar cross-sectional shape corresponding to the non-planar portion.

The non-planar portion may have at least one of a convex portion formed to have a shape protruded from the surface of the substrate and a concave portion formed to have a depressed shape.

The unit pixels may be arranged on an x-y matrix, and at least one non-planar portion may be disposed in each unit pixel. Each non-planar portion may comprise one of a convex portion and a concave portion.

The non-planar portion may comprise a corrugated protrusion or concave portion.

### BRIEF DESCRIPTION OF THE DRAWINGS

The above and other aspects of the present invention will become more apparent by describing in detail exemplary embodiments thereof with reference to the attached drawings in which:

FIG. 1 is a schematic equivalent circuit diagram of an organic electro-luminescent display (OELD) according to an embodiment of the present invention;

FIG. 2 shows a schematic layout of one pixel of the OELD illustrated in FIG. 1;

FIG. 3 is a cross-sectional view taken along line A-A′ of FIG. 2;

FIG. 4 shows a schematic cross-section of one pixel of the OELD illustrated in FIG. 1;

FIGS. 5 and 6 show embodiments of a substrate used in the OELD illustrated in FIG. 1 according to embodiments of the present invention.

FIG. 7 shows a symbolic relationship between a substrate and a light emitting unit of a conventional OELD; and

FIGS. 8A through 8D illustrate substrates of an OELD according to another embodiments of the present invention.

### DETAILED DESCRIPTION OF THE INVENTION

Hereinafter, the present invention will be described more fully with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, lengths and sizes of layers and regions may be exaggerated for clarity.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “below” or “lower” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

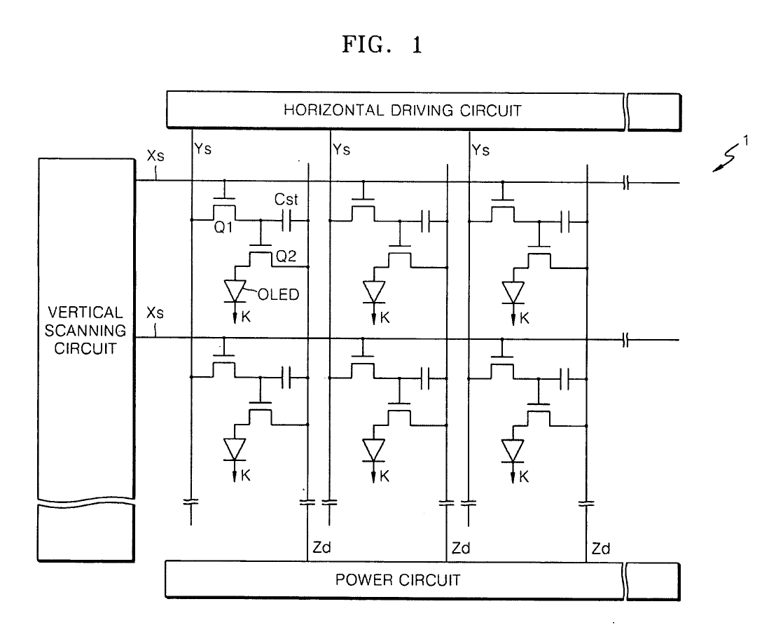

As illustrated in FIG. 1, in an organic electro-luminescent display (OELD), a plurality of parallel X lines Xs and a plurality of parallel Y lines Ys are disposed to cross one another and constitute a matrix structure. Z lines Zd are disposed to be parallel to the Y lines Ys while being separated from the Y lines Ys by a predetermined distance. Each pixel is disposed in a region surrounded by the X lines Xs, the Y lines Ys, and the Z lines Zd.

Each of the X lines Xs is a scan line to which a vertical scan signal is applied, and each of the Y lines Ys is a data line to which a horizontal driving signal as an image signal is applied. Each of the X lines Xs is connected to a vertical driving circuit, and each of the Y lines Ys is connected to a horizontal driving circuit. Each of the Z lines Zd is connected to a power circuit for an OELD operation.

Each pixel comprises two transistors Q1 and Q2 and one storage capacitor Cst. In each pixel, a gate and a source of a switching transistor Q1 are connected to the X lines Xs and the Y lines Ys, and a drain of the switching transistor Q1 is connected to a gate of a driving transistor Q2. The storage capacitor Cst which stores information according to pixels by accumulating charges applied by operating the switching transistor Q1 is connected in parallel to the gate and a source of the driving transistor Q2. An anode of the OELD is connected to a drain of the driving transistor Q2. A cathode K of the OELD corresponds to a common electrode shared by all pixels.

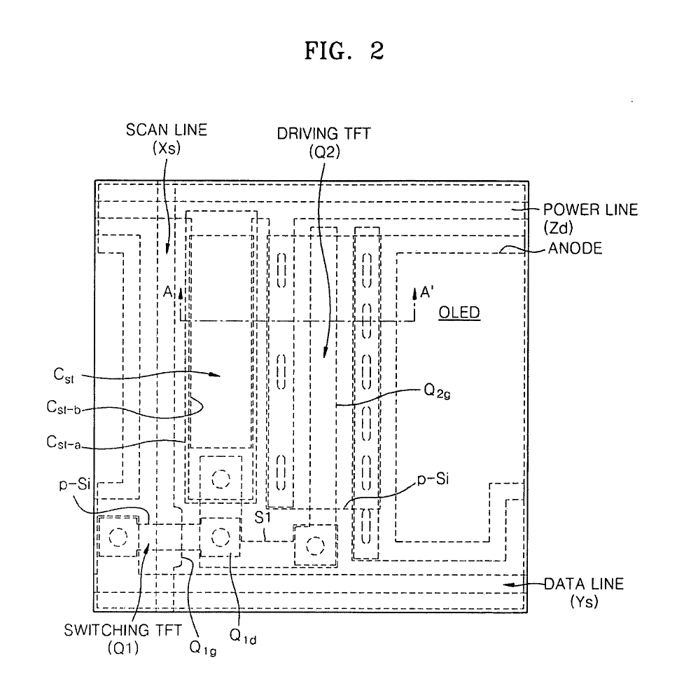

Specifically, referring to FIG. 2, the Y lines Ys which are data lines and the Z lines Zd which are Vdd lines are disposed in parallel to one another in upper and lower portions of FIG. 2, and the X lines Xs which are scan lines are disposed to cross the Y lines Ys and the Z lines Zd. The switching transistor Q1 is positioned in a portion in which the X line Xs and the Y line Ys cross each other, and the driving transistor Q2 is disposed close to a portion in which the X line Xs and the Z line Zd cross each other. The storage capacitor Cst is disposed between the switching transistor Q1 and the driving transistor Q2. One-side electrode Cst-b of the storage capacitor Cst extends from the Z lines Zd, and the other-side electrode Cst-a of the storage capacitor Cst is connected to a drain Q1d of the switching transistor Q1 and a gate Q2g of the driving transistor Q2 via an interconnection layer S1. A gate Q1g of the switching transistor Q1 extends from the X lines Xs.

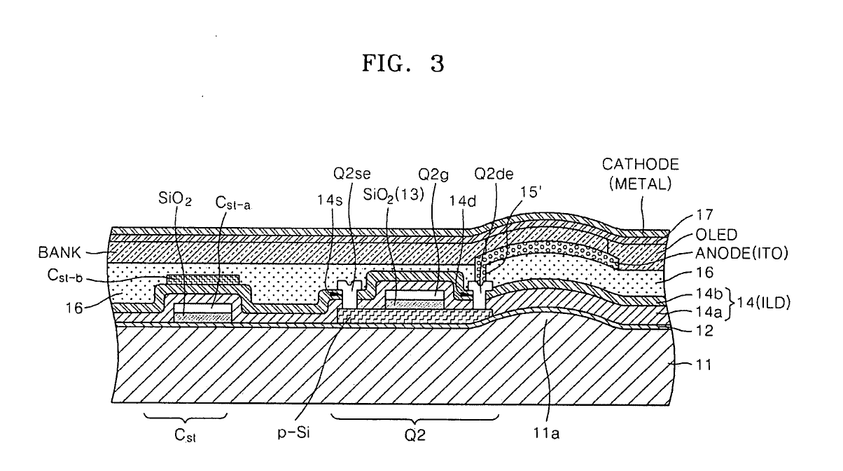

FIG. 3 shows a cross-section taken along line A-A′ of FIG. 2, that is, a latitudinal cross-section of the storage capacitor Cst and the driving transistor Q2. Referring to FIG. 3, a buffer layer 12 is formed using an insulating material such as SiO₂ or SiON on a substrate 11, and the storage capacitor Cst and the driving transistor Q2 are formed on the buffer layer 12. The driving transistor Q2 comprises a polycrystalline silicon (p-Si) layer including a source Q2s and a drain Q2d formed on the buffer layer 12 and a gate insulating layer 13 and a gate Q2g formed of SiO₂ on the p-Si layer. An interlayer dielectric (ILD) layer 14 comprising a first insulating layer 14a and a second insulating layer 14b formed of SiO₂ and SiNx is formed on the driving transistor Q2. Via holes 14s and 14d which communicate with a source and a drain of the p-Si layer are formed in the ILD layer 14, and a metallic source electrode Q2se and a drain electrode Q2de are formed on the via holes 14s and 14d.

Meanwhile, the storage capacitor Cst comprises a lower electrode Cst-a and an upper electrode Cst-b which are simultaneously formed of the same material as a material used in forming the gate Q2g, and an ILD layer 14 between the lower electrode Cst-a and the upper electrode Cst-b.

Meanwhile, an insulating layer 16 is formed on the storage capacitor Cst and the driving transistor Q2, and a via hole 15′ corresponding to an electrical component such as the drain electrode Q2de of the driving transistor Q2 is formed in the insulating layer 16. An anode formed of a transparent conductive material such as indium tin oxide (ITO) is formed on the via hole 15′, and a bank formed of an insulating material is formed around the via hole 15′. An organic light emitting display (OLED) comprising a hole transport layer (HTL), an emission layer (EML), and an electron transport layer (ETL), which are well known, is formed on the anode surrounded by the bank, and a metallic cathode is formed on the OLED, and a passivation layer 17 for protecting a cathode is formed on the cathode. A switching transistor has not been described above but the switching transistor is fabricated simultaneously with the driving transistor, and each of silicon, a gate insulating layer, a gate, an ILD layer, a source electrode, and a drain electrode are simultaneously formed using the same material.

In addition to such a general structure, according to the present invention, at least a non-planar portion corresponding to the OLED is disposed on a substrate 11. As illustrated in FIG. 3, the OLED is indented three-dimensionally. Indentation of the OLED is formed by a protrusion 11a that will be formed on the substrate. According to this, due to an increase in the surface area of the substrate 11, the area of the OLED increases. One or more non-planar portions which cause an increase in the surface area of the substrate 11 in this way may be provide in each pixel. The increase in the area of the OLED, that is, due to the increase in the light emission area of the OLED causes substantial improvement in aspect ratio in a limited area. When an aspect ratio increases in this way, the light emission area of the OLED increases and light emission of desired brightness can be obtained at a lower voltage compared to the prior art. Thus, the durability of the OLED can be improved by a low driving voltage.

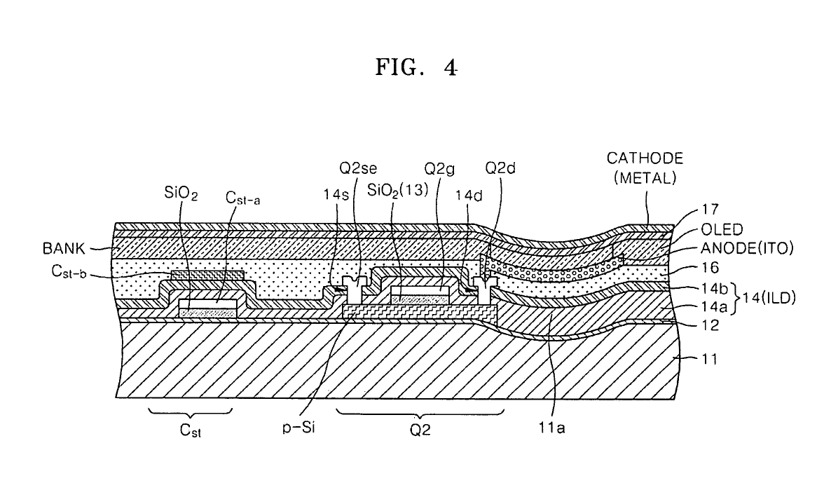

The non-planar portion described above may also be provided by a concave portion 11b illustrated in FIG. 4, as well as by the protrusion 11a on the substrate 11 illustrated in FIG. 3.

Meanwhile, the convex portion (the protrusion) 11a or the concave portion 11b may extend to a lower portion of the OLED and to the entire unit pixel, that is, a lower portion of the entire region comprising a driving unit and the OLED. As such, the driving unit in which a transistor and a capacitor are disposed, as well as the OLED may also be deformed three-dimensionally by the convex portion 11a and the concave portion 11b.

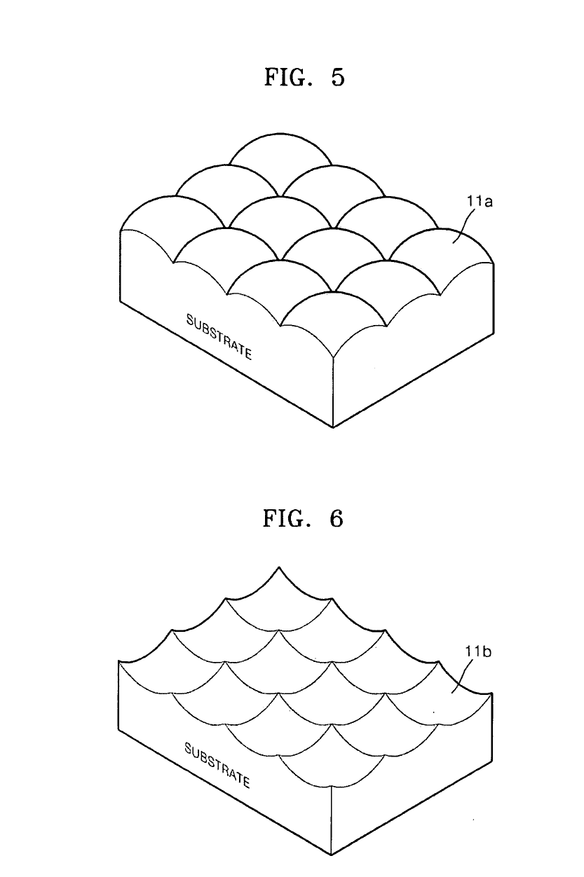

FIGS. 5 and 6 illustrate embodiments of a substrate for causing three-dimensional deformation of the OELD as described above. FIGS. 5 and 6 are somewhat exaggerated. The substrate has a non-planar portion whose surface deformed three-dimensionally in this way so that a driving unit and a light emitting unit to be formed on the substrate can be formed without a large problem. This is because the driving unit and the light emitting unit are formed to a much smaller thickness compared to the thickness of the substrate and improvement in the surface of the substrate does not affect forming of the driving unit and the light emitting unit and operations thereof.

The OELD according to the above-described embodiment has a basic so-called 2 transistors-1 capacitor (2T-1C) driving unit. A larger number of transistors and capacitors may be added to the driving unit as a display is made larger and a pixel is more highly defined. Thus, the OELDs illustrated in FIGS. 1 and 3 are illustrative and do not restrict the technical scope of the present invention.

As a display is made larger and a pixel is more highly defined, for example, a compensation circuit for compensating a threshold voltage of a driving transistor is added. As such, the area of the driving unit in a unit pixel increases and the light emitting unit, that is, the area of the OLED is reduced. Although the area of the OLED is reduced, a non-planar portion such as a convex portion or a concave portion for extending the surface of the substrate is formed on the substrate in this way so that an effective light emission surface in the reduced light emitting unit can be extended.

In detail, according to the present invention, an OELD having an improved aspect ratio in the same area by the concave portion or the convex portion can be obtained. The OELD according to the present invention constitutes an OLED having a larger area than the area of a conventional display in the same area due to improvement in an aspect ratio in the same area so that the life span and performance of the display can be improved.

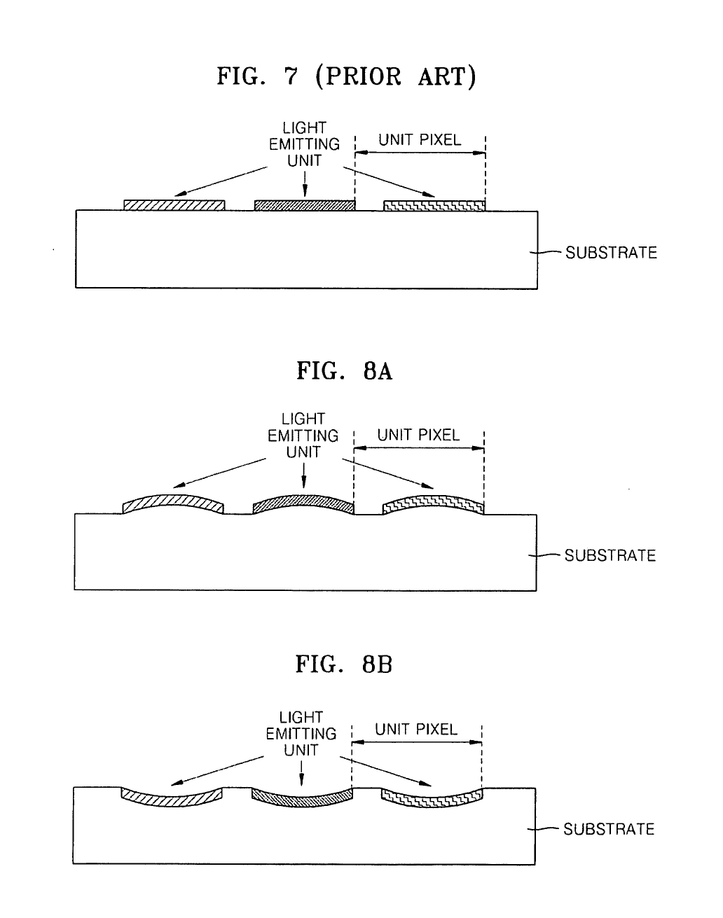

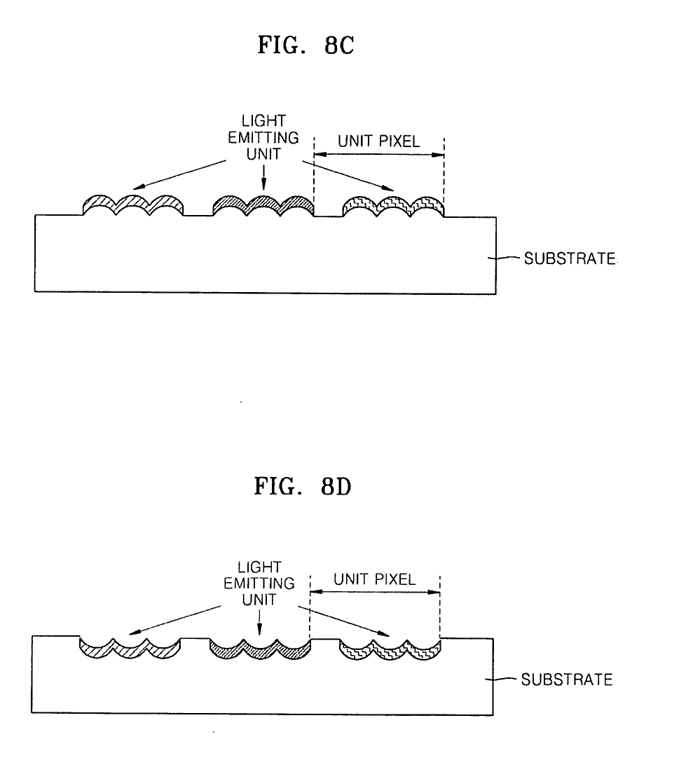

FIG. 7 illustrates the structure of a light emitting unit, that is, OLED, per unit pixel of a conventional OELD symbolically, and FIGS. 8A through 8D illustrate three-dimensional deformation of a light emitting unit per unit pixel caused by a non-planar portion formed on a substrate and enlargement of the effective area of the light emitting unit caused by three-dimensional deformation according to the present invention.

As illustrated in FIG. 7, since the light emitting unit is formed on a flat substrate, the area of the substrate and the area of the light emitting unit are the same.

As illustrated in FIG. 8A, a substrate according to an experimental embodiment of the present invention has a cross-sectional structure protruded by a convex portion. Thus, the area of a light emitting unit increases in the same area and an aspect ratio is improved.

As illustrated in FIG. 8B, a substrate according to another experimental embodiment of the present invention has a structure in which grooves are periodically formed by a concave portion. Thus, the area of a light emitting unit in the same area increases and an aspect ratio is improved.

A substrate according to another experimental embodiment of the present invention illustrated in FIG. 8C has a cross-sectional structure protruded to have a corrugated shape. The corrugated shape is a shape in which a concave portion and a convex portion coexist in one protruded portion. Thus, the area of a light emitting unit also increases in the same area and an aspect ratio is improved.

A substrate according to another experimental embodiment of the present invention illustrated in FIG. 8D has a cross-sectional structure dented to have a corrugated shape. Thus, the area of a light emitting unit also increases in the same area and an aspect ratio is improved.

According to the present invention, the OELD having an improved aspect ratio in the same area by the concave portion or the convex portion can be obtained. The OELD according to the present invention constitutes an OLED having a larger area than the area of a conventional display due to improvement in an aspect ratio in the same area such that the life span and performance of a display are improved.

The present invention can be applied to an active light emitting display device or a well-known spontaneous display device according to unit pixels as well as the OELD.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An OELD (organic electro-luminescent display) comprising:
a plurality of unit pixels having an organic light emitting unit and a driving unit for driving the organic light emitting unit; and
a substrate supporting the unit pixels,
wherein the substrate has a non-planar portion corresponding to the light emitting unit and increasing a surface area, and the light emitting unit has a non-planar cross-sectional shape corresponding to the non-planar portion.

2. The OELD of claim 1, wherein the non-planar portion has at least one of a convex portion formed to have a shape protruded from the surface of the substrate and a concave portion formed to have a depressed shape.

3. The OELD of claim 1, wherein at least one non-planar portion is disposed in each unit pixel.

4. The OELD of claim 3, wherein each non-planar portion comprises one of a convex portion and a concave portion.

5. The OELD of claim 1, wherein the non-planar portion comprises a corrugated protrusion.

6. The OELD of claim 1, wherein the non-planar portion comprises a corrugated concave portion.
